(19) United States
(12) Patent Application Publication
(10) Pub. No.: US 2010/0084646 A1
(43) Pub. Date: Apr. 8, 2010

(54) LIGHT-EMITTING ELEMENT AND DISPLAY DEVICE

(75) Inventors: Noriyuki Matsusue, Osaka (JP); Kenji Okumoto, Kyoto (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/598,151

(22) PCT Filed: Feb. 24, 2009
(86) PCT No.: PCT/JP2009/000784

§ 371 Date: Oct. 29, 2009

(30) Foreign Application Priority Data
Mar. 4, 2008 (JP) 2008-053085

(51) Int. Cl. H01L 51/50

(52) U.S. Cl. 257/40; 257/59; 257/72; 257/E51.018; 257/79

(57) ABSTRACT

A light emitting element, including a light emitting section and a connecting section, the light emitting section and the connecting section being provided over a substrate, along the in-plane direction of the substrate, an insulating section being formed between the light emitting section and the connecting section, the light emitting element, including: the light emitting section including: a bottom electrode, a phosphor layer formed over the bottom electrode; a first charge transporting layer formed over the phosphor layer; and a first top electrode formed over the first charge transporting layer, the connecting section including: an auxiliary electrode; a second charge transporting layer formed over the auxiliary electrode and connected electrically to the first charge transporting layer of the light emitting section; and a second top electrode formed over the second charge transporting layer and connected electrically to the first top electrode of the light emitting section; the insulating section electrically insulates, with the auxiliary electrode of the connecting section, the bottom electrode and the phosphor layer of the light emitting section, and further, a HOMO (eV) and a LUMO (eV) in the first charge transporting layer are identical to a HOMO (eV) and a LUMO (eV) in the second charge transporting layer, yet further, a work function Ip (eV) of the first top electrode is identical to a work function Ip (eV) of the second top electrode, and the HOMO (eV), the LUMO (eV) and the work function Ip (eV) satisfy the following expression.

|(|HOMO|−Ip)−(Ip−|LUMO|)|≦0.1 eV

### BACKGROUND OF THE INVENTION

1. Technical Field

The present invention relates to a light-emitting element using organic electroluminescence, and further to a display device wherein light emitting elements using electroluminescence are two-dimensionally arranged.

2. Background Art

A light emitting element wherein a thin film made of an organic substance is sandwiched between two electrodes and luminescence is obtained by undergoing the application of a voltage is called an organic electroluminescence element, which may be referred to as an organic EL element hereinafter. Organic EL elements using an organic low molecular material were found out in the 1960s, as shown in the document of M. Pope at al., Journal of Chemical Physics vol. 38, pp. 2042-2043, 1963. Thereafter, in the 1980s, element structures having practical process and characteristics were developed, as shown in the document of C. W. Tang, S. A. Vanslyke, Applied Physics Letters vol. 51, pp. 913-915, 1987. About organic EL elements using a low molecular material, organic thin films thereof can be formed by vacuum evaporation, and the elements can be formed under conditions that the incorporation of impurities or dusts in a vacuum process thereinto is slight. The organic elements have characteristics that the lifespan is long and pixel defects are less generated. In the early 1990s, organic EL elements using a polymeric material were reported, as shown in the document of J. H. Burroughes et al., Nature No. 347, pp. 539-541, 1990. About organic EL elements using a polymeric material, organic thin films thereof can be obtained by painting a solution or dispersion wherein a polymer is dissolved in a solvent in a wet manner. The organic EL elements have a characteristic that the loss of the material is small because of a simple process under the atmospheric pressure. Any one of the organic EL elements has characteristics that bright natural light is given, the viewing angle dependency thereof is small, the area can easily be made large and a fine array can easily be produced, and other characteristics; thus, in recent years, the development of organic EL elements as light generating source for displays or as light sources for illumination has been advanced.

Old organic EL elements as seen in Non-Patent Document 2 each have a structure wherein a transparent bottom electrode is laminated on a transparent substrate and light emitted from an organic layer is taken out from the substrate side. As their top electrode, a metallic element or the like is used, and light emitted from the organic light is reflected thereon. Organic EL elements having this structure are called bottom emission type organic EL elements. In general, the bottom electrode, which functions as an anode, is selected from materials having a large work function while the top electrode, which functions a cathode, is selected from materials having a small work function.

In the meantime, there are organic ELs having a structure wherein an opaque electrode, an organic phosphor layer, and a transparent top electrode are successively laminated on a substrate, and light emitted from the organic phosphor layer is taken out from the transparent top electrode. The organic EL elements having this structure are called top emission type organic EL elements.

When top emission type organic EL elements are applied to an active matrix organic EL display, which includes organic EL elements and thin film transistors (hereinafter referred to as TFTs) for driving the elements, the EL elements are more suitable than bottom emission type organic EL elements. In other words, in bottom emission type organic EL elements, emitted light is taken out from the substrate side; thus, the organic EL light emitting section area in the pixel area is restricted into regions other than the TFTs and electric wiring, which are opaque, on the substrate. Simultaneously, it is necessary to make the area of the TFT and that of the electric wiring inside the pixels as small as possible in order to make the occupation area of the organic ELs large. Thus, the flexibility of the design is low. On the other hand, in top emission type organic EL elements, emitted light is taken out from the side opposite to their substrate, that is, from the upper side; thus, the area of the TFT section on the substrate side can be made large up to the pixel area. This makes it possible to make the channel width of the TFTs wide, thereby increasing the current amount to be supplied to the organic EL elements, or increase the number of the TFTs to form a current compensating circuit, thereby restraining an in-plane brightness distribution of the display. Additionally, the area of the organic EL elements in the pixel area can be made large so that the lifespan of the display can be enhanced.

In the meantime, in top emission type organic EL elements, it is necessary to take out light from the top electrode thereof; therefore, for example, indium tin oxide (hereinafter referred to as ITO), which is a transparent electrode, a thin film metal or a thin film alloy that is high in light transmissibility is used. However, the electrode high in light transmissibility has a large resistance value; thus, in the top electrode, a voltage gradient is generated so that a voltage drop is easily generated to cause a problem that brightness unevenness is generated. Thus, disclosed is a method of arranging, between pixels wherein individual light emitting elements are arranged, an auxiliary electrode connected to a top electrode, so that a drop in the voltage is restrained by the auxiliary electrode.

However, in a structure wherein an organic layer is formed as a continuous film common to individual pixels, the entire surface of its auxiliary electrode is covered with the organic layer. In such a case, by effect of the organic layer on the auxiliary electrode, electrical connection between the auxiliary electrode and the top electrode may be insufficient. Against this problem, disclosed are the removal of the organic layer by a laser, as shown in Japanese Patent Laid-Open Publication No. 2007-52966, the electrical connection based on a projection structure, as shown in Japanese Patent Laid-Open Publication No. 2007-93397, and others.

However, in the laser-ray-radiating method described in Japanese Patent Laid-Open Publication No. 2007-52966, the radiation of a laser beam, and other processes are increased so that the productivity is declined. In the projection-structure-using method described in Japanese Patent Laid-Open Publication No. 2007-93397, the structure of the device becomes complicated so as to cause a problem that the position of an auxiliary electrode is not easily made consistent with that of projection regions in fine pixels.

Against the problem, disclosed is a light emitting element having at least a first buffer layer, a phosphor layer and a second buffer layer, in which in a pixel region the first buffer layer, which exhibits hole transporting performance, the second buffer layer, which exhibits electron transporting performance, or both of the layers are sandwiched between a top electrode and an auxiliary electrode, so as to be connected electrically to each other, as shown in Japanese Patent Laid-Open Publication No. 2007-73499. In this structure, the top electrode functions as a cathode of a light emitting element section, so that electrons are injected into the second buffer layer. The bottom electrode functions as an anode of the light emitting element section, so that holes are injected into the first buffer layer.

However, according to the structure described in the Japanese Patent Laid-open Publication No. 2007-73499, in connecting sections each including the auxiliary electrode, the top electrode and the buffer layer(s), the top electrode functions as an anode, and the bottom electrode functions as a cathode. For example, in a case where only the first buffer layer, which has hole transporting performance, is present between the connecting sections, holes are injected from the top electrode, which has a small work function, so that sufficient holes cannot be injected. Thus, there is a problem that electrical connection between the top electrode and the buffer layer is not sufficiently performed.

### SUMMARY OF THE INVENTION

Thus, an object of the invention is to provide a top emission type organic EL element wherein light emission evenness resulting from a drop in the voltage is restrained.

In order to solve the above problems, there is a light emitting element of the present invention including a light emitting section and a connecting section, the light emitting section and the connecting section being provided over a substrate, along the in-plane direction of the substrate, an insulating section being formed between the light emitting section and the connecting section, the light emitting element, including:

the light emitting section including:
a bottom electrode;
a phosphor layer formed over the bottom electrode;
a first charge transporting layer formed over the phosphor layer; and
a first top electrode formed over the first charge transporting layer;

the connecting section including:
an auxiliary electrode;
a second charge transporting layer formed over the auxiliary electrode and connected electrically to the first charge transporting layer of the light emitting section; and
a second top electrode formed over the second charge transporting layer and connected electrically to the first top electrode of the light emitting section,

wherein the insulating section electrically insulates, with the auxiliary electrode of the connecting section, the bottom electrode and the phosphor layer of the light emitting section,

wherein a HOMO (eV) and a LUMO (eV) in the first charge transporting layer are identical to a HOMO (eV) and a LUMO (eV) in the second charge transporting layer,

wherein a work function Ip (eV) of the first top electrode is identical to a work function Ip (eV) of the second top electrode, and

wherein the HOMO (eV), the LUMO (eV) and the work function Ip (eV) satisfy the following expression.

|(|HOMO|−Ip)|(Ip−|LUMO|)|≦0.1 eV

The first top electrode and the second top electrode may be formed as one common layer. Further, the first charge transporting layer and the second charge transporting layer may be formed as one common layer.

Further preferably, the first charge transporting layer and second charge transporting layer may include a bipolar material capable of transporting holes and electrons. The first and second charge transporting layers may include one or more materials and one or more metallic materials, the one or more materials being selected from the group consisting of oxadiazole derivatives, phenanthroline derivatives, carbazole derivatives, and organometallic complexes, and the one or more metallic materials being selected from alkali metals or alkaline earth metals.

The first top electrode and second top electrode may include indium tin oxide, and the first charge transporting layer and second charge transporting layer may include 4,4′-di(N-carbazolyl)biphenyl.

Further, the first charge transporting layer and second charge transporting layer may be electron transporting layers.

Further, the first top electrode, second top electrode and the auxiliary electrode may be made of the same material.

The light emitting element may further include a TFT for selecting one out of a plurality of light emitting sections and for causing light emission from the selected light emitting section.

A display device of the present invention configured such that a plurality of light emitting elements are two-dimensionally arranged.

According to the light emitting element of the invention, in order to inject electric charges from the top electrode to the organic phosphor layer of the light emitting section, the auxiliary electrode, and the connecting section, wherein the charge transporting layer is sandwiched between the auxiliary electrode and the top electrode, are formed. By the matter that the light emitting element has the connecting section, electrons are injected from the top electrodes to the charge transporting layer on the light emitting section side, and further holes are injected from the top electrodes to the charge transporting layer on the connecting section side. By causing the work function of the top electrode and the HOMO and LUMO of the charge transporting layer in the connecting section to satisfy the predetermined relational expression, light emission unevenness resulting from a drop in the voltage can be restrained. This makes it possible to provide a top emission type organic EL element very good in light emission characteristics.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a sectional view of a light emitting element according to an embodiment 1 of the invention when the element is viewed from a direction perpendicular to a light emitting plane of the element;

FIG. 2 is an energy diagram of individual layers of the light emitting element in FIG. 1; and

FIG. 3A is an energy diagram showing a charge injection barrier from top electrodes of a light emitting element of Example 1 to each of its organic EL section side and its connecting section side, and FIG. 3B is an energy diagram showing a charge injection barrier from top electrodes of a light emitting element of Comparative Example 1 to each of its organic EL section side and its connecting section side.

### DETAILED DESCRIPTION OF THE PREFERRED EMBODIMENTS

With reference to the attached drawings, light emitting elements according to embodiments of the invention will be described hereinafter. In the drawings, the same reference numbers are attached to substantially the same members, respectively.

### First Embodiment

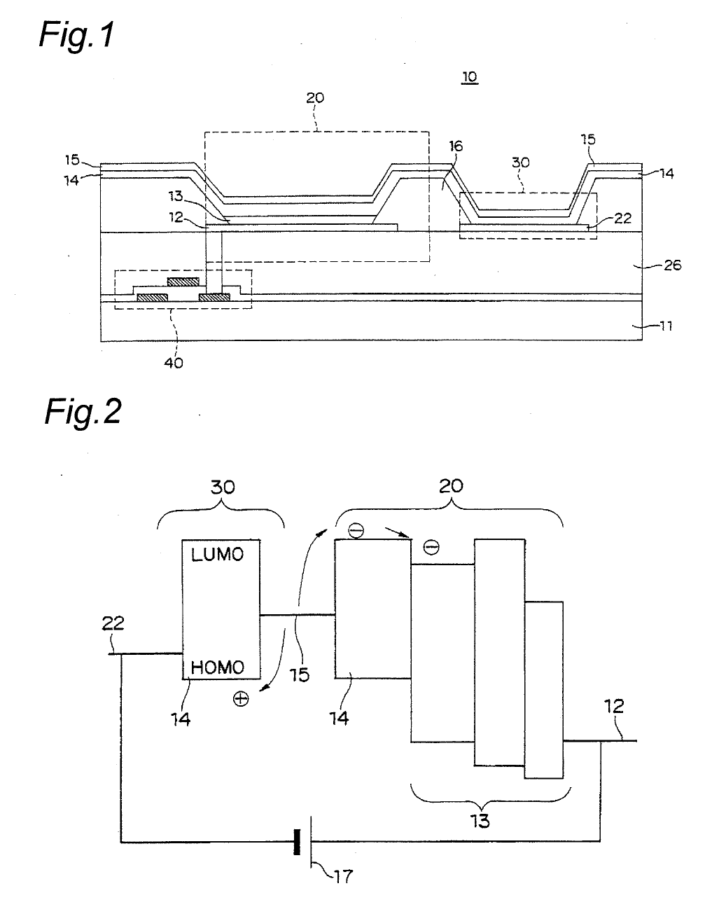

FIG. 1 is a sectional view of a light emitting element 10 according to a first embodiment of the invention along a direction perpendicular to a light emitting plane of the element. In this light emitting element 10, on a substrate 11 are successively formed a TFT section 40 and a flattening layer 26. An organic EL section (light emitting section) 20 and a connecting section 30 are arranged on the flattening layer 26 along the in-plane direction thereof, so as to sandwich an insulating section 16 therebetween. The organic EL section 20 has a structure wherein a bottom electrode 12, an organic phosphor layer 13, a first charge transporting layer 14, and a first top electrode 15 are successively laminated. The connecting section 30 has a structure wherein an auxiliary electrode 22, a second charge transporting layer 14, and a second top electrode 15 are successively laminated. The organic EL section 20 and the connecting section 30 are electrically insulated therefrom each other by the insulating section 16 arranged therebetween. In the light emitting element 10 of the embodiment 1, the first top electrode 15 and the second top electrode 15 are formed as one common layer. The first charge transporting layer 14 and the second charge transporting layer 14 are also formed as one common layer. Thus, the bottom electrode 12 and the organic phosphor layer 13 of the organic EL section 20 are electrically insulated from the auxiliary electrode 22 of the connecting section 30 by the insulating section 16.

As shown in an energy diagram in FIG. 2, in this light emitting element 10, the bottom electrode 12 of the organic EL section 20 is used as an anode, the auxiliary electrode 22 of the connecting section 30 is used as a cathode, a direct current power source 17 is connected to the two, and a voltage is applied thereto so as to cause light emission. In this case, in the organic EL section 20, holes flow from the bottom electrode 12 into the organic phosphor layer 13 while electrons flow from the top electrode 15 through the charge transporting layer 14 into the organic phosphor layer 13. In this way, light is emitted from the organic phosphor layer 13.

In this light emitting element 10, the HOMO (eV) and the LUMO (eV) of the charge transporting layers 14 continuous with each other in the organic EL section 20 and the connecting section 30, and the work function Ip (eV) of the top electrodes 15 satisfy a relationship of the following expression:

|(|HOMO|−Ip)−(Ip−|LUMO|)|≦0.1 eV

This means that the difference between: the difference between the energy level of the top electrodes 15 and the HOMO of the charge transporting layers 14 (|HOMO|−Ip); and that difference between the energy level of the top electrodes 15 and the LUMO of the charge transporting layers 14 (Ip−|LUMO|) is 0.1 eV or less. In other words, this represents that in the energy diagram in FIG. 2, the energy level of the top electrodes 15 is located at a substantially middle position between the HOMO and the LUMO of the charge transporting layers 14.

When the connecting section 30 as satisfying the relational expression is constructed, the magnitudes of the following charge injection barriers become substantially equal to each other: the injection barrier of electrons from the top electrodes 15 into the charge transporting layer 14 of the organic EL section 20 side; and the injection barrier of holes from the top electrodes 15 into the charge transporting layer 14 on the connecting layer 30 side.

Accordingly, each of the charge injections from the top electrodes 15 into the organic EL section 20 side and the connecting section 30 side can easily be executed. This makes it possible to keep electrical connection to the top electrodes 15 sufficiently through the connecting section 30 so that charge can be sufficiently injected in the organic EL section 20. Thus, light is easily caused to be emitted.

In this light emitting element 10, a single organic EL section is selected from organic El sections equivalent to the organic El section 20 by effect of a TFT or TFTs. The TFT section 40 has at least one TFT, and is formed on the substrate 11. On the TFT section 40, the flattening layer 26 is laid, and a flat plane is formed thereon. The organic EL section 20 and the connecting section 30 are arranged in the flat plane formed by the flattening layer 26 along the in-plane direction thereof.

The following will describe each of the constituent members which constitute this light emitting element 10.

### <Substrate>

The substrate 11 is not particularly limited, and may be, for example, a glass substrate or a quartz substrate. A plastic substrate made of polyethylene terephthalate, polyethersulfone or the like may be used to give bendability to the organic EL. As described above, the structure of the light emitting element of the invention produces a large effect onto top emission type organic EL elements; thus, an opaque plastic substrate or metallic substrate may be used.

### <Thin Film Transistor (TFT) Section>

The organic EL section 20 is driven in an active matrix mode by thin film transistors (TFTs). The TFT section 40 has at least one TFT for selecting the organic EL section 20 and driving the section. In FIG. 1, TFTs are each of a top gate type. The TFTs each include a source region, a drain region, a gate electrode formed over a channel forming region to interpose a gate insulating film therebetween, a source electrode connected electrically to the source region, and a drain region connected electrically to the drain region. The structure of the TFTs is not particularly limited, and may be, for example, of a bottom gate type or of a top gate type.

### <Flattening Layer>

The flattening layer 26 is formed on the TFT section 40, and causes irregularities in the upper of the TFT section 40 to be flattened and further causes the TFT section 40 to be electrically insulated from the organic EL section 20 and the connecting section 30. In the flattening layer 26, connecting holes are made for connecting the source electrodes of the TFT section 40 to the bottom electrode 12 of the organic EL section 20. The material of the flattening layer 26 is not particularly limited, and may be an organic material such as polyimide, or an inorganic material such as silicon oxide (SiO₂).

### <Insulating Section>

The insulating section 16 is formed on the flattening layer 26, and defines an area where the organic EL section 20 is formed, and an area where the connecting section 30 is formed. This insulating section 16 makes it possible to keep electrical insulation certainly between the top electrodes 15 and the bottom electrode 12, and further make the shape of the light emission region of the light emitting element 10 precisely into a desired shape. The material of the insulating section 16 is not particularly limited, and may be an organic material such as polyimide, or an inorganic material such as silicon oxide (SiO₂).

### <Organic EL Section>

The organic EL section 20 has a structure having, on the flattening layer 26, for example, the bottom electrode 12 as an anode, the organic light emitting element 13, the charge transporting layer 14, and the top electrode 15 as a cathode that are successively laminated in this order. In the present embodiment, the charge transporting layer 14 and the top electrode 15 each extend over a plurality of pixels so as to be formed in the form of a common layer over the entire surface.

Each of the layers constituting the organic EL section 20 will be described hereinafter.

### <Bottom Electrode>

The bottom electrode 12 is not particularly limited. A metal having electroconductivity and reflectivity can be satisfactorily used therefor. For example, the following may be used: any metal out of silver, aluminum, nickel, chromium, molybdenum, copper, iron, platinum, tungsten, lead, tin, antimony, strontium, titanium, manganese, indium, zinc, vanadium, tantalum, niobium, lanthanum, cerium, neodymium, samarium, europium, palladium, copper, nickel, cobalt, molybdenum, platinum, and silicon; alloys thereof; and any product wherein two or more thereof are laminated onto each other. The bottom electrode 12 may be constructed as a multi-layered bottom electrode wherein the metal, which has reflectivity, and a transparent electrode made of, for example, indium tin oxide or indium zinc oxide are laminated onto each other.

### <Organic Phosphor Layer>

The organic phosphor layer 13 is not particularly limited, and may be a single phosphor layer made of an organic material, or a phosphor layer wherein layers containing at least one phosphor layer are laminated onto each other. As far as the layer 13 contains at least one phosphor layer, the layer 13 may further contain a layer containing an organic material. The organic layer to be used may be made of a low molecular weight organic compound or a high molecular weight organic compound. The low molecular weight organic compound is not particularly limited, and is preferably formed by resistance-heating vapor deposition. The high molecular weight organic compound is not particularly limited, and is preferably formed by a casting method such as a spin casting method from a solution, a coating method such as dip coating, or a wet printing method such as an ink-jetting method.

Specific examples of the organic material used in the phosphor layer include oxynoid compounds, perylene compounds, coumarin compounds, azacoumarin compounds, oxazole compounds, oxadiazole compounds, perynone compounds, pyrrolopyrrole compounds, naphthalene compounds, anthracene compounds, fluorene compounds, fluoranthene compounds, tetracene compounds, pyrene compounds, coronene compounds, quinolone compounds and azaquinolone compounds, pyrazoline derivatives and pyrazolone derivatives, rhodamine compounds, chrysene compounds, phenanthrene compounds, cyclopentadiene compounds, stylbene compounds, diphenylquinone compounds, styryl compounds, butadiene compounds, dicyanomethylenepyrane compounds, dicyanomethylenethiopyrane compounds, fluorescein compounds, pyrylium compounds, thiapyrylium compounds, selenapyrylium compounds, telluropyrylium compounds, aromatic aldadiene compounds, oligophenylene compounds, thioxanthene compounds, anthracene compounds, cyanine compounds, acridine compounds, metal complexes of 8-hydroxyquinoline compounds, metal complexes of 2,2′-bipyridine compounds, complexes each made from a Schiff salt and a group III metal, oxine metal complexes, rare earth element complexes, and other fluorescent materials, which are described in Japanese Patent Laid-open Publication No. H05-163488. The phosphor layer may be formed by vapor deposition, spin coating, casting or the like.

The organic phosphor layer 13 may be formed as a laminated structure including a charge transporting layer, such as a hole transporting layer or electron transporting layer, and a phosphor layer as well as only a phosphor layer.

### <Charge Transporting Layer>

The charge transporting layer 14 is preferably a layer having bipolarity, which is capability of transporting both of electrons and holes. This charge transporting layer 14 may include an organic material made of one or more selected from oxadiazole derivatives, phenanthroline derivatives, carbazole derivatives and organometallic complexes, and a metal material such as an alkali metal or an alkaline earth metal.

(a) Specific usable materials of the oxadiazole derivatives include 2-(4-biphenylyl)-5-(4-tert-butylphenyl)-1,3,4-oxadiazole (abbreviated to PBD) (work function: 5.9 eV, energy gap Eg: 3.5 eV, HOMO: −5.9 eV, and LUMO: −2.4 eV), and 1,3-bis[5-(4-tert-butylphenyl)-1,3,4-oxadiazole-2-yl]benzene (abbreviated to OXD-7) (work function: 5.9 eV, energy gap Eg: 3.7 eV, HOMO: −5.9 eV, and LUMO: −2.2 eV).

(b) Specific usable materials of the phenanthroline derivatives include Bathocuproin (abbreviated to BCP) (work function: 7.0 eV, energy gap Eg: 3.5 eV, HOMO: −7.0 eV, and LUMO: −3.5 eV).

(c) Specific usable materials of the carbazole derivatives include 4,4′-di(N-carbazolyl)biphenyl (abbreviated to CBP) (work function: 6.3 eV, energy gap Eg: 3.2 eV, HOMO: −6.3 eV, and LUMO: −3.1 eV), and 4,4′,4″-tris(N-carbazoyl)triphenylamine (abbreviated to TCTA) (work function: 5.7 eV, energy gap Eg: 3.3 eV, HOMO: −5.7 eV, and LUMO: −2.4 eV).

(d) Specific usable examples of the metal complexes include tris(8-quinolinolato)aluminum (abbreviated to Alq3) (work function: 6.0 eV, energy gap Eg: 2.7 eV, HOMO: −6.0 eV, and LUMO: −3.3 eV), and bis(2-methyl-8-quinolinolato)-(4-phenylphenolato)aluminum (abbreviated to BAlq) (work function: 5.9 eV, energy gap Eg: 2.9 eV, HOMO: −5.9 eV, and LUMO: −3.0 eV).

The metal material constituting the charge transporting layer 14 may be an alkali metal or an alkaline earth metal. Preferred usable examples of the metal material include lithium, rubidium, cesium, calcium and barium; however, the metal material is not particularly limited.

### <Top Electrode>

The top electrode 15 is not particularly limited. Indium tin oxide (ITO) (work function Ip: 4.6 eV), or indium zinc oxide (IZO) may be used therefor.

This top electrode 15 may be formed preferably by DC sputtering, RF sputtering, magnetron sputtering, ECR sputtering, plasma-assistant vapor deposition or the like; however, the method for the formation is not particularly limited.

### <Connecting Section>

The connecting section 30 is arranged over the substrate 11 and in the same plane on which the light emitting section 20 is arranged, so as to sandwich the insulating section 16 between the section 30 and the section 20. The connecting section 30 is formed in such a manner that the auxiliary electrode 22, the charge transporting layer 14, and the top electrode 15 are successively laminated. The charge transporting layer 14 and the top electrode 15 are preferably formed to be continuous with the charge transporting layer 14 and the top electrode of the organic EL section 20, respectively. In this connecting section 30, the auxiliary electrode 22 is connected electrically to the top electrode 15 through the charge transporting layer 14. This makes it possible to restrain a voltage drop in the top electrode.

### <Auxiliary Electrode>

The auxiliary electrode 22 is formed on the flattening layer 26. The auxiliary electrode 22 is not particularly limited. For example, the following may be used therefor: any metal out of silver, aluminum, nickel, chromium, molybdenum, copper, iron, platinum, tungsten, lead, tin, antimony, strontium, titanium, manganese, indium, zinc, vanadium, tantalum, niobium, lanthanum, cerium, neodymium, samarium, europium, palladium, copper, nickel, cobalt, molybdenum, platinum, and silicon; alloys thereof; and any product wherein two or more thereof are laminated onto each other. The auxiliary electrode 22 may be a transparent electrode made of, for example, indium tin oxide or indium zinc oxide. The transparent electrode may be used in the form of a laminate with one or more of the metals.

### <Charge Transporting Layer>

The charge transporting layer 14 in the connecting section 30 may be equal to or similar to the charge transporting layer 14 in the organic EL section 20. The charge transporting layer 14 in the connecting section 30 may be formed continuously with the charge transporting layer 14 in the organic EL section 20.

### <Top Electrode>

The top electrode 15 in the connecting section 30 may be equal to or similar to the top electrode 15 in the organic EL section 20. The top electrode 15 in the connecting section 30 is connected electrically to the top electrode 15 in the organic EL section 20. The top electrode 15 in the connecting section 30 may be formed continuously with the top electrode 15 in the organic EL section 20.

### <Relational Expression Between the HOMO (eV) and the LUMO (eV) of the Charge Transporting Layers, and the Work Function Ip (eV) of the Top Electrodes>

In the light emitting element 10 of the embodiment 1, the following expression is satisfied by the same HOMO (highest occupied molecular orbital) (eV) and the same LUMO (lowest unoccupied molecular orbital) (eV) in the charge transporting layer 14 of the organic EL section 20 and the charge transporting layer 14 of the connecting section 30, and the same work function Ip (eV) of the top electrode 15 of the organic EL section 20 and the connecting section 30:

|(|HOMO|−Ip)−(Ip−|LUMO|)|≦0.1 eV

This means that the difference between: the difference between the energy level (−Ip) of the top electrodes 15 and the HOMO of the charge transporting layers 14 (|HOMO|−Ip); and that between the energy level (−Ip) of the top electrodes 15 and the LUMO of the charge transporting layers 14 (Ip−|LUMO|) is 0.1 eV or less. In other words, this represents that in the energy diagram in FIG. 2, the energy level of the top electrodes 15 is located at a substantially middle position between the HOMO and the LUMO of the charge transporting layers 14.

### Example 1

A light emitting element of example 1 is a specific structure of the light emitting element according to the embodiment 1. In this light emitting element, an organic EL section (light emitting section) and a connecting section were separately formed on a substrate along the in-plane direction thereof to sandwich an insulating section therebetween. As the substrate 11, a glass substrate (flat glass manufactured by Matsunami Glass Ind., Ltd.) was used.

### <Insulating Section>

An insulating layer was formed on the glass substrate (flat glass manufactured by Matsunami Glass Ind., Ltd.), and then patterned to form the insulating section 16. By the section 16, an area where the organic EL section 20 was to be formed, and an area where the connecting section 30 was to be formed were partitioned from each other.

### <Organic EL Section (Light Emitting Section)>

(a) An alloy electrode (MoCr) composed of 97% of molybdenum and 3% of chromium was formed into the form of a film of 100 nm thickness on the glass substrate (flat glass manufactured by Matsunami Glass Ind., Ltd.) by sputtering. The film was patterned into a predetermined shape by photolithography, so as to form a lower layer of the bottom electrode 12.

(b) Next, indium tin oxide (ITO) was formed into the form of a film by sputtering, and the film was patterned into a predetermined anode shape by photolithography, so as to form an upper layer of the bottom electrode 12. In this way, the bottom electrodes 12, which had two layers of the upper and lower layers, were formed.

(c) Next, the following three layers were formed as the organic phosphor layer 13:

1) First, PEDOT (trade name: Baytron P AI 4083, manufactured by TA Chemical Co., Ltd.) was formed into a film of 60 nm thickness by spin coating, and then the film was heated on a hot plate at a temperature of 200° C. for 10 minutes to form a hole injecting layer.

2) Next, from a solution of poly[(9,9-dioctylfluorenyl-2,7-diyl)-co-(4,4′-(N-(4-sec-butylphenyl))diphenylamine)] (manufactured by American Dye Source) in toluene, a film of 20 nm thickness was formed by spin coating, and then the film was heated on a hot plate at 200° C. in nitrogen for 30 minutes to form a hole transporting layer.

3) Next, from a solution of poly[(9,9-dihexylfluoren-2,7-diyl)-alt-co(benzo[2,1,3]thiadiazole-4,7-diyl] (manufactured by American Dye Source) in xylene, a film of 70 nm thickness was formed by spin coating, and then the film was heated on a hot plate at 130° C. for 10 minutes to form a phosphor layer.

As described above, the organic phosphor layer 13 having the three-layer structure was formed.

(d) Next, barium and Alq3 were vapor-codeposited (or co-evaporated) at a ratio by volume of 5/100 to form the charge transporting layer 14 having a film thickness of 20 nm.

(e) Lastly, according to plasma-assistant vapor deposition (a film forming apparatus (manufactured by Sumitomo Heavy Industries, Ltd.) was used), indium tin oxide (ITO) was formed into the form of a film, 100 nm in thickness, as the top electrode 15.

As described above, the organic EL section 20 was formed.

### <Connecting Section>

The following will describe a process for forming a connecting section.

(1) An alloy electrode composed of 97% of molybdenum and 3% of chromium was formed into the form of a film, 100 nm in thickness, as a lower layer of the auxiliary electrode 22 on the glass substrate by sputtering, and then the film was patterned into a predetermined shape by photolithography.

(2) Next, indium tin oxide was formed into the form of a film as an upper of the auxiliary electrode 22 by sputtering, and then the film was patterned into a predetermined anode shape by photolithography. As described above, the auxiliary electrode 22 having a two-layer structure of the upper and lower layers was formed.

(3) Next, the charge transporting layer 14 and the top electrode 15 were successively formed continuously with the charge transporting layer 14 and the top electrode 15 of the organic EL section 20, respectively.

Herein, the formation of the layers has been described separately from the formation of the individual layers of the organic EL section; however, the layers continuous with the individual layers of the organic EL section, respectively, were each formed by substantially simultaneous lamination.

As described above, the connecting section 30 was formed.

As described above, the organic EL section 20 and the connecting section 30 were formed to produce a light emitting element.

### [Evaluation]

When the auxiliary electrode 22 of the connecting section 30 was used as a cathode and the bottom electrode 12 of the organic EL section 20 was used as an anode to apply a voltage thereto, electrons were injected from the top electrodes 15 to the charge transporting layer 14 on the organic EL section 20 side while holes were injected from the top electrodes 15 to the charge transporting layer 14 on the connecting section 30 side. In this way, light was emitted from the organic phosphor layer 13, and the emission brightness thereof and the current density were measured. As a result, an emission efficiency of 11 cd/A and a driving voltage of 6.3 eV (at 10 mA/cm²) were exhibited. In such a manner, a good light emission was obtained.

An atmospheric photoelectron spectrometer (Riken Keiki Co., Ltd.) was used to measure the work functions of the ITO electrode, the Alq3 film, and the BCP film. As a result, the work function of the ITO was 4.6 eV, that of the Alq3 was 6.0 eV, and that of the BCP film was 6.7 eV.

Absorption ends of the light absorption spectra were measured to determine the energy gaps Eg of the Alq3 film and the BCP film. As a result, the energy gap Eg of the Alq3 film was 2.7 eV, and that Eg of the BCP film was 3.5 eV.

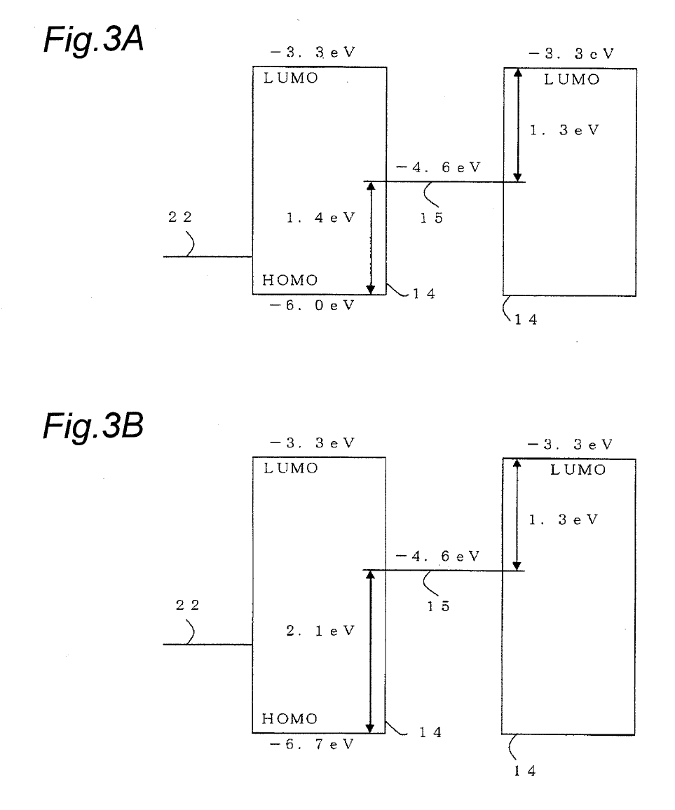

FIG. 3A is an energy diagram of the individual layers of the light emitting element 10 of Example 1 before the voltage was applied thereto. As shown in the energy diagram in FIG. 3A, the electron injection barrier from the top electrodes 15 to the charge transporting layer 14 on the organic EL section 20 side is 1.3 eV. The hole injection barrier from the top electrodes (ITO) 15 to the charge transporting layer 14 on the connecting section 30 side is 1.4 eV. For this reason, sufficient electrons can be injected from the top electrodes 15 to the organic phosphor layer 13 of the organic EL section 20, and further a sufficient electrical connection can be realized between the top electrodes 15 and the auxiliary electrode 22.

In other words, it is necessary to inject electrons from the top electrodes 15 to the charge transporting layer 14 on the organic EL section 20 side and further inject holes from the top electrodes 15 to the charge transporting layer 14 on the connection section 30 side. It is therefore desired that the energy level of the top electrodes 15 (—work function Ip) is located at a middle position between the HOMO and the LUMO of the charge transporting layer 14 between one of the top electrodes 15 and the auxiliary electrode 22. The charge transporting layer 14 formed between one of the top electrodes 15 and the auxiliary electrode 22 desirably has bipolarity, which is capability of transporting both of holes and electrons.

### Comparative Example 1

In a light emitting element of Comparative Example 1, charge transporting layers continuous with each other in an organic EL section and a connecting section were formed as vapor-codeposited films made of Bathocuproin (BCP) (work function: 7.0 eV, energy gap: 3.5 eV, HOMO: −7.0 eV, and LUMO: −3.5 eV), which is a phenanthroline derivative, and barium. The light emitting element was produced under the same conditions as in Example 1 except that the material of this charge transporting layer was changed. About this light emitting element, the same measurement as in Example 1 was made. As a result, an emission efficiency of 2.6 cd/A and a driving voltage of 12.3 eV (at 10 mA/cm²) were exhibited. As understood from the measurement results, the light emission was weak.

As shown in an energy diagram in FIG. 3B, in the light emitting element of Comparative Example 1, the electron injection barrier from the top electrodes 15 to the charge transporting layer 14 on the organic EL section 20 side is 1.4 eV. However, the hole injection barrier to the charge transporting layer 14 on the connecting section 30 side is 2.1 eV. It therefore appears that: the injection of holes from the top electrodes 15 to the connecting section 30 side is insufficient, and the electrical connection between one of the top electrodes 15 and the auxiliary electrode 22 is insufficient; thus, the light emission in Comparative Example 1 is weak.

The light emitting element according to the invention gives uniform light emission, which does not have unevenness. Therefore, the element is suitable for being applied to an active matrix organic EL display, wherein the element is combined with a TFT.

1. A light emitting element, comprising a light emitting section and a connecting section, the light emitting section and the connecting section being provided over a substrate, along the in-plane direction of the substrate, an insulating section being formed between the light emitting section and the connecting section, the light emitting element, comprising:
the light emitting section including:
a bottom electrode;
a phosphor layer formed over the bottom electrode;
a first charge transporting layer formed over the phosphor layer; and
a first top electrode formed over the first charge transporting layer, the connecting section including:
an auxiliary electrode;
a second charge transporting layer formed over the auxiliary electrode and connected electrically to the first charge transporting layer of the light emitting section; and
a second top electrode formed over the second charge transporting layer and connected electrically to the first top electrode of the light emitting section,
wherein the insulating section electrically insulates, with the auxiliary electrode of the connecting section, the bottom electrode and the phosphor layer of the light emitting section,
wherein a HOMO (eV) and a LUMO (eV) in the first charge transporting layer are identical to a HOMO (eV) and a LUMO (eV) in the second charge transporting layer,
wherein a work function lp (eV) of the first top electrode is identical to a work function lp (eV) of the second top electrode, and
wherein the HOMO (eV), the LUMO (eV) and the work function Ip (eV) satisfy the following expression.

|(|HOMO|−Ip)−(Ip−|LUMO|)|≦0.1 eV

2. The light emitting element according to claim 1, wherein the first top electrode and the second top electrode are formed as one common layer.

3. The light emitting element according to claim 1, wherein the first charge transporting layer and the second charge transporting layer are formed as one common layer.

4. The light emitting element according to claim 1, wherein the first charge transporting layer and second charge transporting layer include a bipolar material capable of transporting holes and electrons.

5. The light emitting element according to claim 4, wherein the first and second charge transporting layers include one or more materials and one or more metallic materials, the one or more materials being selected from the group consisting of oxadiazole derivatives, phenanthroline derivatives, carbazole derivatives, and organometallic complexes, and the one or more metallic materials being selected from alkali metals or alkaline earth metals.

6. The light emitting element according to claim 4, wherein
the first top electrode and second top electrode include indium tin oxide, and
the first charge transporting layer and second charge transporting layer include 4,4′-di(N-carbazolyl)biphenyl.

7. The light emitting element according to claim 1, wherein
the first charge transporting layer and second charge transporting layer are electron transporting layers.

8. The light emitting element according to claim 1, wherein
the first top electrode, second top electrode and the auxiliary electrode are made of the same material.

9. The light emitting element according to claim 1, further comprising a thin film transistor (TFT) for selecting one out of a plurality of light emitting sections for causing light emission from the selected light emitting section.

10. A display device, wherein a plurality of light emitting elements as recited in claim 1 are two-dimensionally arranged.
